(19) United States
(12) Patent Application Publication
(10) Pub. No.: US 2003/0122236 A1
(43) Pub. Date: Jul. 3, 2003

(54) Semiconductor device having multi-chip package structure

(76) Inventors: Shibaek Nam, Incheon-city (KR); Oseob Jeon, Seoul (KR); Chulho Heo, Bucheon-city (KR)

Correspondence Address: SKJERVEN MORRILL MACPHERSON LLP, Three Embarcadero Center, 28th Floor, San Francisco, CA, 94111, US

(21) Appl. No.: 10/038,714

(22) Filed: Jan. 2, 2002

(51) Int. Cl. H01L 21/44; H01L 23/48; H01L 29/40

(52) U.S. Cl. 257/685; 438/107; 438/118; 257/686; 257/777

(57) ABSTRACT

A semiconductor device having a multi-chip package structure and a manufacturing method therefor are provided. The semiconductor device includes a lead frame, a first integrated circuit chip, and a second integrated circuit chip. The first integrated circuit chip is attached to a top surface of the lead frame by a conductive adhesive, and the second integrated circuit chip is attached to a top surface of the first integrated circuit chip by an insulating adhesive tape or an insulation epoxy adhesive.

### FIELD OF THE INVENTION

The present invention relates to semiconductor devices, and more particularly, to a semiconductor device having a multi-chip package structure.

### BACKGROUND

Multiple integrated circuit (“IC”) chips can be combined in a single package for some applications of semiconductor devices. These are generally referred to as “multi-chip packages.” For example, in a power semiconductor device, a smart power switching (“SPS”) product may contain a control IC chip, which is a driving device, and a transistor chip, which is a switching device, mounted together horizontally on a lead frame, which must be large enough to accommodate both chips side-by-side. During a packaging process, a common method for insulating a multi-chip package is to attach one chip to the lead frame by inserting a ceramic plate or epoxy mold compound (“EMC”) plate between die adhesives or to use a liquid non-conductive adhesive, such as an epoxy. However, there are manufacturing problems with this method.

Inserting a ceramic plate or an EMC plate between die adhesives is problematic. First, the ceramic plate is breakable and expensive, so the manufacturing cost increases. Second, the overall packaging process is made more complicated since several additional steps are required. These steps include inserting the ceramic or EMC plate and curing to harden the die adhesives. Third, the overall packaging process is not only complicated but also is likely to cause faults in a die adhesive, such as void, delamination, and die tilt. Such faults in a die adhesive lower product yield rate and product reliability. The product yield rate is also lowered by the additional process steps of inserting a ceramic or EMC plate and curing the die adhesives. There is a need for a cheaper and simpler process.

Using a liquid non-conductive adhesive is also problematic. First, the thickness of a layer formed from liquid non-conductive adhesive is not uniform so that the chip which is attached using the liquid non-conductive adhesive may ultimately be mounted in a slanted position relative to an underlying surface. Second, in the course of hardening a liquid non-conductive adhesive after an IC chip is attached, a void occurs in the liquid conductive adhesive, so that it is difficult to ensure the reliability of the resultant product. Third, the IC chip and the non-conductive adhesive may not be completely attached together because a crevice may form at the adhesion boundary; this is generally referred to as “delamination.” A crevice also degrades product reliability. Furthermore, the likelihood of delamination increases for a semiconductor device having an EMC plate since a device is most prone to delamination at functions which are flat surfaces (e.g., the backside of an IC chip, the top or backside of an EMC plate, or the top of a lead frame). There is a need for a level and uniform adhesive.

### SUMMARY

In one embodiment, a semiconductor device having a multi-chip package structure is provided. The semiconductor device has a lead frame, a first integrated circuit chip attached to a top surface of the lead frame by a conductive adhesive, and a second integrated circuit chip attached to a top surface of the first integrated circuit chip by an insulating adhesive tape or an insulation epoxy adhesive.

In another embodiment, the semiconductor device is a power semiconductor device. The power semiconductor device has a lead frame, a switching device attached to a top surface of the lead frame by a conductive adhesive, and a driving device attached to a top surface of the switching device by an insulating adhesive tape or insulation epoxy adhesive.

According to an embodiment, a method to manufacture a semiconductor device having a multi-chip package structure is provided. The method includes attaching a first integrated circuit chip to a top surface of a lead frame with a conductive adhesive and attaching a second integrated circuit chip to a top surface of the first integrated circuit chip with an insulating adhesive tape or an insulation adhesive epoxy. The use of the insulating adhesive tape or an insulation adhesive epoxy simplifies manufacturing and lowers costs.

According to an embodiment, a method to manufacture a power semiconductor device having a multi-chip package is provided. The method includes attaching a switching device to a top surface of a lead frame with a conductive adhesive and attaching a driving device to a top surface of the switching device with an insulating adhesive tape or an insulation epoxy adhesive.

### BRIEF DESCRIPTION OF THE DRAWINGS

For a more complete understanding of the present invention and for further features and advantages, reference is now made to the following description, taken in conjunction with the accompanying drawings, in which:

FIG. 1 is a cross-sectional view of a semiconductor device having a multi-chip package structure with an insulating adhesive tape, according to an embodiment of the present invention;

FIG. 2 is a cross-sectional view of an insulating adhesive tape;

FIGS. 3 and 4 are cross-sectional views of a semiconductor device having a multi-chip package structure with an insulation epoxy adhesive, according to embodiments of the present invention;

FIG. 5 is a flow diagram of a method for manufacturing a semiconductor device with an insulating adhesive tape, according to an embodiment of the present invention; and

FIG. 6 is a flow diagram of a method for manufacturing a semiconductor device with an insulation epoxy adhesive, according to an embodiment of the present invention.

In the drawings, like numerals are used for like and corresponding parts.

### DETAILED DESCRIPTION

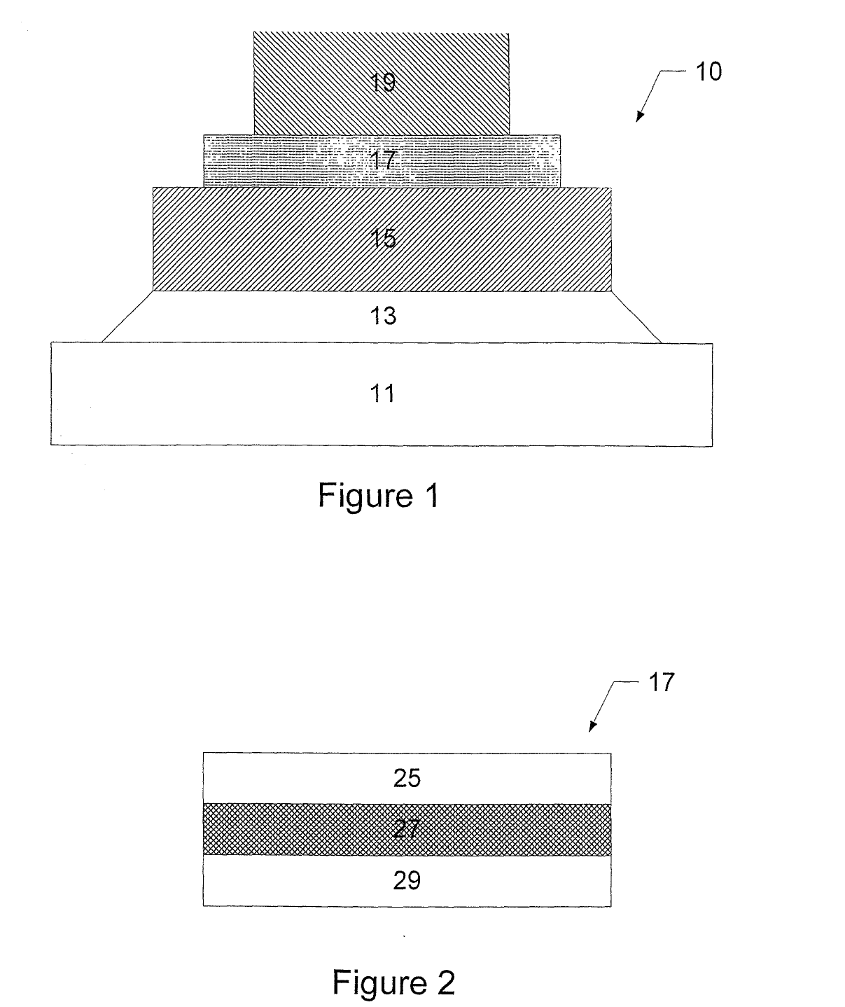

FIG. 1 is a cross-sectional view of a semiconductor device 10 having a multi-chip package structure with an insulating adhesive tape 17, according to an embodiment of the present invention. In one embodiment, the semiconductor device 10 can be a power semiconductor device. The semiconductor device 10 includes a lead frame 11, a first integrated circuit chip 15, and a second integrated circuit chip 19. The lead frame 11 is generally rectangular, but can have the same shape as that used in Dual in Line, Small Out-line, or for other forms of packages. The first integrated circuit chip 15 can be a switching device, such as, for example, a transistor chip or a sense field-effect transistor (FET). The first integrated circuit chip 15 can have a top surface with a given area. The top surface may have a metallization layer, such as aluminum, for wire bonding. The second integrated circuit chip 19 can be a control device or a driving device, such as, for example, a control integrated circuit chip. The second integrated circuit chip 19 can have a bottom surface with a given area.

The first integrated circuit chip 15 can be attached to a top surface of the lead frame 11 by a conductive adhesive 13. In one embodiment, the first integrated circuit chip 15 may not have a passivation layer on its top surface; only a metallization layer may be formed on the top surface. The conductive adhesive 13 may be solder or any other suitable adhesive. The conductive adhesive may provide an insulation withstand voltage in the range of about 500 volts to about 1,000 volts.

The second integrated circuit chip 19 is attached to the top surface of the first integrated circuit chip 15 by an insulating adhesive tape 17. The amount of surface area covered by the insulating adhesive tape 17 can be smaller than the entire top surface of the first integrated circuit chip 15 and larger than the entire bottom surface of the second integrated circuit chip 19. The insulating adhesive tape 17 can comprise a polyimide base resin. The polyimide base resin may be a thermosetting resin or a thermoplastic resin. The insulating adhesive tape 17 provides a level and uniform attachment for the second integrated circuit chip 19.

In one embodiment, the insulating adhesive tape 17 has a single-layered structure comprising a polyimide base resin, which can be a thermosetting resin or a thermoplastic resin. In another embodiment, the insulating adhesive tape 17 has a multi-layered structure comprising a first adhesive layer 25, an insulating layer 27, and a second adhesive layer 29, as shown in FIG. 2. The first adhesive layer 25 and the second adhesive layer 29 are typically formed of a polyimide base resin, which may be a thermosetting resin or a thermoplastic resin. The insulating layer 27 may comprise polyimide having a large dielectric strength. In one embodiment, the dielectric strength of the insulating layer 27 can be such that a voltage of higher than about 5,000 V can be insulated per area having a length or breadth of about 25 μm at a temperature of about 200° C.

If the insulating adhesive tape 17 is used in a product requiring an insulation withstand voltage of about 10,000 V, then the thickness of the first adhesive layer 25 and the second adhesive layer 29 are about 25 μm, and the thickness of the insulating layer 27 is about 50 μm, so that the overall thickness of the insulating adhesive tape 17 is 100 μm. If the insulating adhesive tape 17 is used in a product requiring a higher insulation withstand voltage, then the insulating layer 27 may be thicker. Conversely, if the insulating adhesive tape 17 is used in a product demanding a lower insulation withstand voltage, then the insulating layer 27 may be thinner, or the insulating adhesive tape 17 may be a single-layered tape comprising polyimide without the insulating layer. Thus, if the quality and thickness of an insulating adhesive tape 17 are adjusted depending on the degree of an insulating withstand voltage that a product requires, it is possible to ensure a sufficient insulation withstand voltage between two chips without the use of a ceramic or an EMC plate.

The insulation adhesive tape 17 may serve to insulate the first integrated circuit chip 15 from the second integrated circuit chip 19, thus eliminating the need for a dielectric passivation layer on the top surface of the first integrated circuit chip 15.

Thus, an embodiment of the present invention simplifies a die attaching process by using an insulating adhesive tape 17 to attach the second integrated circuit chip 19 to the first integrated circuit chip 15. Since neither a ceramic plate nor an EMC plate is used, and the step of forming a passivation layer may be eliminated, this embodiment of the present invention lowers the manufacturing cost and increases product yield rate and product reliability. Furthermore, the elimination of a ceramic or an EMC plate, as well as the step of forming a passivation layer, simplifies the manufacturing process by reducing the number of required process steps. Also, the insulating adhesive tape 17 can be a uniform thickness, which provides a level surface for mounting the second integrated circuit chip 19, thereby eliminating or substantially reducing any slant that might occur.

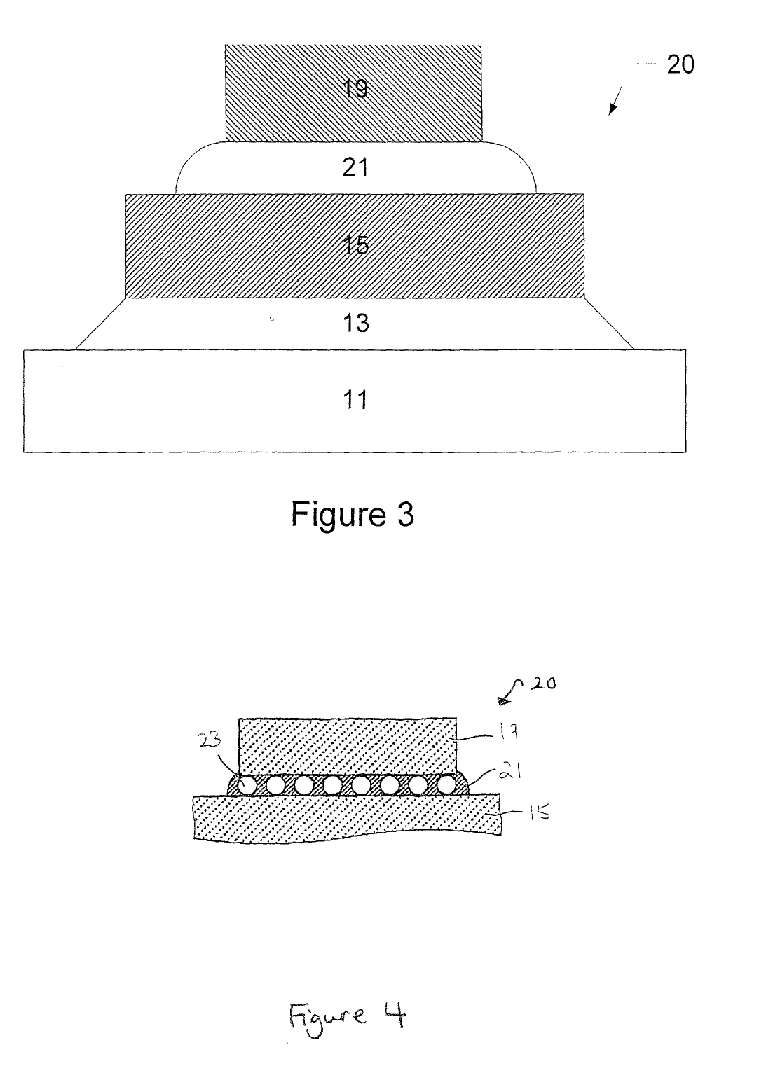

FIG. 3 is a cross-sectional view of a semiconductor device 20 having a multi-chip package structure with an insulation epoxy adhesive 21, according to an embodiment of the present invention. In one embodiment, the semiconductor device 20 is a power semiconductor device. The semiconductor device 20 includes a lead frame 11, a first integrated circuit chip 15, and a second integrated circuit chip 19. The first integrated circuit chip 15 can be a switching device, such as, for example, a transistor chip. The first integrated circuit chip 15 can have a top surface with a given area. The second integrated circuit chip 19 can be a control device or a driving device, such as, for example, a control IC chip. The second integrated circuit chip 19 can have a bottom surface with a given area.

The first integrated circuit chip 15 can be attached to a top surface of the lead frame 11 by a conductive adhesive 13. In one embodiment, the first integrated circuit chip 15 may not have a passivation layer on its top surface; only a metallization layer may be formed on the top surface. The conductive adhesive 13 may be solder or any other suitable adhesive. The conductive adhesive may provide an insulation withstand voltage in the range of about 500 volts to about 1,000 volts.

The second integrated circuit chip 19 is attached to the top surface of the first integrated circuit chip 15 by an insulation epoxy adhesive 21. The amount of surface area covered by the insulation epoxy adhesive 21 can be smaller than the entire top surface of the first integrated circuit chip 15 and larger than the entire bottom surface of the second integrated circuit chip 19. The insulation epoxy adhesive 21 may be any liquid, nonconductive epoxy, such as a thermosetting liquid epoxy.

The insulation epoxy adhesive 21 may serve to insulate the first integrated circuit chip 15 from the second integrated circuit chip 19, thus eliminating the need for a dielectric passivation layer on the top surface of the first integrated circuit chip 15. This embodiment eliminates a process step of forming a dielectric passivation layer. The elimination of a process step simplifies manufacturing and lowers package cost. Manufacturing is also simplified and package cost lowered by the elimination of a ceramic or an EMC plate. Since neither a ceramic plate nor an EMC plate is used, the elimination of a ceramic or an EMC plate simplifies the manufacturing process by reducing the number of required process steps and increases product yield rate and product reliability. Product yield rate and product reliability is increased in part because of the elimination of delamination defects between the liquid adhesive and the ceramic or EMC plate, since the present invention does not use a ceramic or EMC plate.

FIG. 4 is a cross-sectional view of a semiconductor device 20 having a multi-chip package structure with an insulation epoxy adhesive 21, according to an embodiment of the present invention. In this embodiment, spherical beads 23 of relatively uniform diameter may be added to the insulation epoxy adhesive 21. These spherical beads prevent the second integrated circuit chip 19 from tilting in the event that the insulation epoxy adhesive 21 is not applied uniformly or the viscosity of insulation epoxy adhesive 21 decreases. Die tilt is undesirable since it may decrease the reliability of the semiconductor device 10. Materials used for the beads 23 include silica. In one embodiment, the diameter of the beads 23 may be uniform. When the diameter of the beads 23 is uniformly adjusted to a range of about 25 μm to about 100 μm, the beads 23 in the insulation epoxy adhesive 21 may uniformly support the second integrated circuit chip 19, thereby eliminating or substantially reducing any slant that might occur.

As the diameter of the beads 23 decreases, the dielectric strength between the first integrated circuit chip 15 and the second integrated circuit chip 19 decreases. Conversely, as the diameter of the beads 23 increases, the dielectric strength between the first integrated circuit chip 15 and the second integrated circuit chip 19 increases. Accordingly, the dielectric strength between the first integrated circuit chip 15 and the second integrated circuit chip 19 can be selected by adjusting the diameter of the beads 23.

### EXAMPLE 1

The configuration of a semiconductor device according to embodiments of the present invention provides numerous advantages. For example, if the semiconductor device is a power semiconductor device and the first integrated circuit chip 15 comprises a switching device, embodiments of the present invention improve the reliability of products and decrease the cost of manufacturing. In one embodiment, the switching device may not include a passivation layer.

When reliability tests such as a temperature cycle test were performed on a power semiconductor device having a passivation layer, cracks occurred in the passivation layer, resulting in defects. In addition, when a reliability test of applying a reverse bias voltage corresponding to 80% of a regular voltage between collector and emitter of a switching device for a predetermined time was performed on a power semiconductor device having a passivation layer, defects occurred which related to the breakdown voltage of the switching device.

Two different types of tests—temperature cycle tests and reliability tests of applying a reverse bias voltage—were performed on a power semiconductor device having a passivation layer and a power semiconductor device not having a passivation layer. First, for a temperature cycle test, power semiconductor devices were fabricated using switching devices not having a passivation layer, according to an embodiment of the present invention, and power semiconductor device were fabricated using switching devices having a passivation layer. Thereafter, a predetermined number of power semiconductor devices were sampled from the power semiconductor devices not having a passivation layer, and a predetermined number of power semiconductor devices were sampled from the power semiconductor device having a passivation layer. The samples were subjected to a cycle, in which a temperature alternated between −65° C. and 150° C. for a predetermined time, repeated 100, 200, and 500 times under the same conditions. Next, occurrences of rejects due to the above-described changes in temperature were checked through an electrical test.

In the case of power semiconductor devices having a passivation layer, there were no rejects among 50 samples when the cycle was repeated 100 times. There was one reject among 50 samples when the cycle was repeated 200 times. There were six rejects among 49 samples when the cycle was repeated 500 times. Therefore, a reject percentage was about 12% for 500 trials.

In the case of power semiconductor devices not having a passivation layer, there were no rejects among 250 samples when the cycle was repeated 100 times and when the cycle was repeated 200 times. There were four rejects among 50 samples when the cycle was repeated 500 times. Therefore, a reject percentage was about 8% for 500 trials. This reject percentage for a power semiconductor device not having a passivation layer is significantly lower than the reject percentage for a power semiconductor device having a passivation layer.

Second, a reliability test was performed. A reverse bias voltage was applied for 300 hours and then breakdown voltage characteristics were checked. In the case of power semiconductor devices having a passivation layer, six rejects were found among 76 samples. Thus, the reject percentage was about 7.8%. In the case of power semiconductor devices not having a passivation layer, no rejects were found among 76 samples. Thus, the reliability of a power semiconductor device not having a passivation layer is significantly better than the reliability of a power semiconductor device having a passivation layer.

The results of the temperature cycle tests and the reliability tests show a marked improvement in reliability of a power semiconductor device not having a passivation layer over the reliability of a power semiconductor device having a passivation layer. In addition to the improvement in reliability, a power semiconductor device not having a passivation layer reduces manufacturing cost and simplifies manufacturing processes because a process of forming a passivation layer on the switching device is omitted.

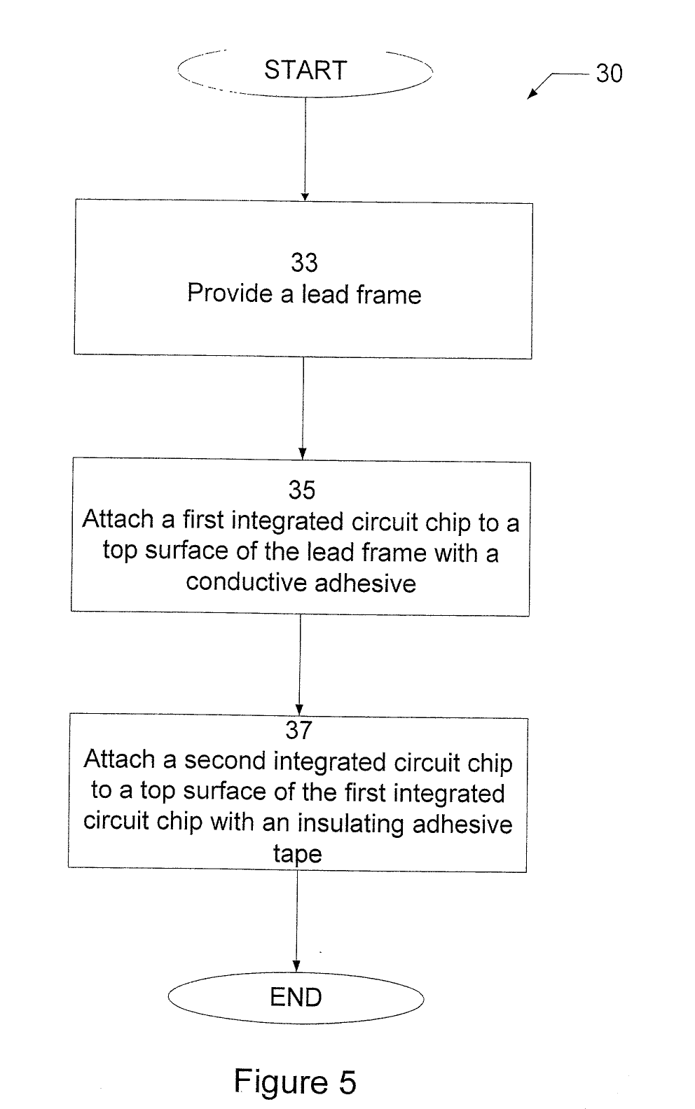

FIG. 5 is a flow diagram of a method 30 for manufacturing a semiconductor device having a multi-chip package structure with an insulating adhesive tape 17, according to an embodiment of the present invention. At step 33, a lead frame 11 is provided. The lead frame 11 is generally rectangular, but can have the same shape as that used in Dual in Line, Small Out-line, or for other forms of packages.

At step 35, a first integrated circuit chip 15 is attached to a top surface of a lead frame 11 with a conductive adhesive 13. In one embodiment, the first integrated circuit chip 15 may not have a passivation layer formed on its top surface. The first integrated circuit chip 15 can be a switching device, such as, for example, a transistor chip or a sense field-effect transistor (FET). The conductive adhesive 13 is may be solder or any other suitable adhesive.

At step 37, a second integrated circuit chip 19 is attached to a top surface of the first integrated circuit chip 15 with an insulating adhesive tape 17. The second integrated circuit chip 19 can be a control device or a driving device, such as, for example, a control integrated circuit chip. The insulating adhesive tape 17 may comprise a polyimide base resin, which may be a thermosetting resin or a thermoplastic resin.

The insulation adhesive tape 17 may insulate the first integrated circuit chip 15 from the second integrated circuit chip 19 and can eliminate the need for a dielectric passivation layer on the top surface of the first integrated circuit chip 15. This embodiment may thus eliminate a process step of forming a dielectric passivation layer, thereby simplifying manufacturing and reducing costs.

The use of the insulation adhesive tape 17 simplifies manufacturing and lowers costs, since the number of required process steps are reduced, and there is no need for a ceramic or an EMC plate. The use of the insulation adhesive tape 17, which provides a level and uniform surface for mounting, also improves product reliability since it substantially reduces or eliminates die slant or tilt, thereby reducing the occurrence of defects.

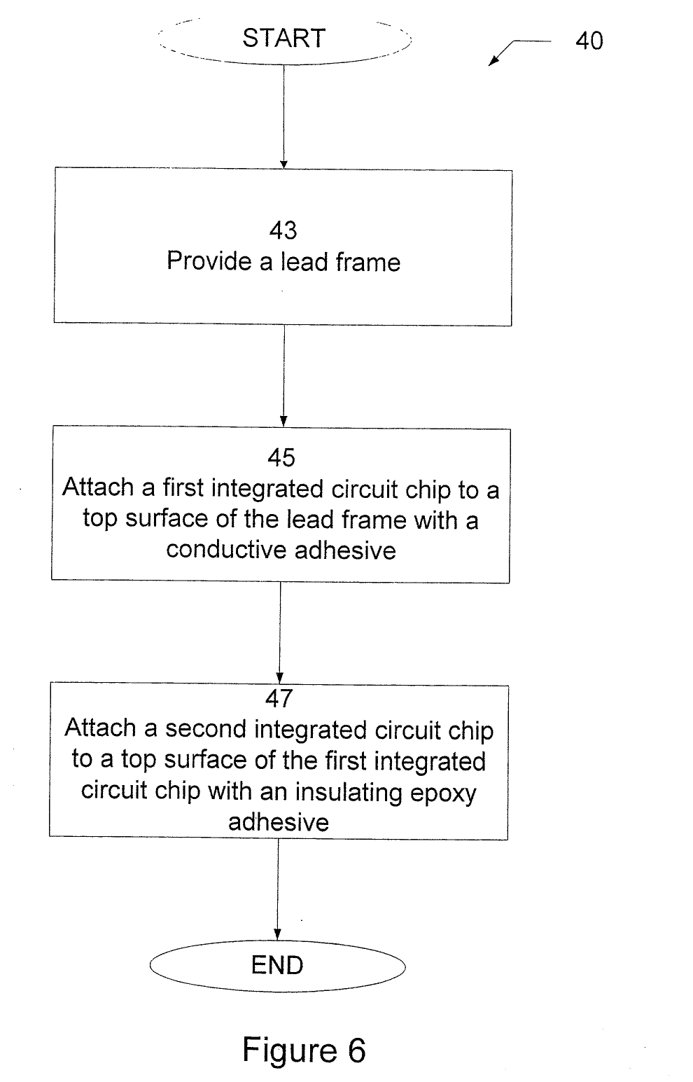

FIG. 6 is a flow diagram of a method 40 for manufacturing a semiconductor device having a multi-chip package structure with an insulation epoxy adhesive 21, according to an embodiment of the present invention. At step 43, a lead frame 11 is provided.

At step 45, a first integrated circuit chip 15 is attached to a top surface of a lead frame 11 with a conductive adhesive 13. In one embodiment, the first integrated circuit chip 15 may not have a passivation layer formed on its top surface. The first integrated circuit chip 15 can be a switching device, such as, for example, a transistor chip or a sense field-effect transistor (FET). The conductive adhesive 13 is may be solder or any other suitable adhesive.

At step 47, a second integrated circuit chip 19 is attached to a top surface of the first integrated circuit chip 15 with an insulation epoxy adhesive 21. The second integrated circuit chip 19 can be a control device or a driving device, such as, for example, a control integrated circuit chip. The insulation epoxy adhesive 21 may be any liquid, non-conductive epoxy, such as a thermosetting liquid epoxy.

In one embodiment, beads 23 may be added to the insulation epoxy adhesive 21. The beads 23 may comprise silica. The beads 23, which provides a level and uniform surface for mounting, improves product reliability since they substantially reduce or eliminate die slant or tilt, thereby reducing the occurrence of defects. The dielectric strength between the first integrated circuit chip 15 and the second integrated circuit chip 19 can be selected by adjusting the diameter of the beads 23.

Optionally, the insulation epoxy adhesive 21 may be cured. Depending on the type of insulation epoxy adhesive 21, the curing temperature may be from about 150° C. to about 200° C., and the curing time may be from about a few minutes to about two hours.

The insulation epoxy adhesive 21 may insulate the first integrated circuit chip 15 from the second integrated circuit chip 19 and can eliminate the need for a dielectric passivation layer on the top surface of the first integrated circuit chip 15. This embodiment may thus eliminate a process step of forming a dielectric passivation layer, thereby simplifying manufacturing and reducing costs.

As described herein, according to embodiments of the present invention, a semiconductor device having a multi-chip package structure is provided. A first IC chip is attached to a top surface of a lead frame by a conductive adhesive, and a second IC chip is attached to a top surface of the first IC chip by an insulating adhesive tape or an insulation epoxy adhesive. The insulating adhesive tape provides a level and uniform attachment of the first IC chip and the second IC chip. The insulation epoxy adhesive is a low-cost adhesive and, where the insulation epoxy adhesive includes beads, also provides a level and uniform attachment of the first IC chip and the second IC chip. The use of either the insulating adhesive tape or the insulation epoxy adhesive lowers costs and simplifies manufacturing by reducing the number of required process steps.

The insulating adhesive tape may have a single-layered structure comprising a polyimide base resin or a multi-layered structure, such as a triple-layered structure comprising of a first adhesive layer, an insulating layer, and a second adhesive layer. In this embodiment, the first and second adhesive layers are typically polyimide base resin. The polyimide base resin can be a thermosetting resin or a thermoplastic resin. The insulating adhesive tape provides a level and uniform adhesive, and the use of the insulating adhesive tape simplifies manufacturing and lowers package cost.

The insulation epoxy adhesive may be a thermosetting liquid epoxy. In one embodiment, the insulation epoxy adhesive comprises beads. The beads can be silica. The diameter of the beads may be about 25 μm to about 100 μm. The insulation epoxy adhesive with the beads provides a level and uniform adhesive, and the use of the insulation epoxy adhesive simplifies manufacturing and lowers package cost.

While particular embodiments of the present invention have been shown and described, it will be obvious to those skilled in the art that changes and modifications may be made without departing from this invention in its broader aspects and, therefore, the appending claims are to encompass within their scope all such changes and modifications as fall within the true spirit and scope of this invention.

What is claimed is:

1. A semiconductor device having a multi-chip package structure, the semiconductor device comprising:
a lead frame;
a first integrated circuit chip attached to a top surface of the lead frame by a conductive adhesive, wherein the first integrated circuit chip does not have a passivation layer on a top surface of the first integrated circuit chip; and
a second integrated circuit chip attached to the top surface of the first integrated circuit chip by an insulating adhesive tape.

2. The semiconductor device of claim 1, wherein the second integrated circuit chip is directly attached to a top surface of the first integrated circuit chip by an insulating adhesive tape.

3. The semiconductor device of claim 1, wherein the first integrated circuit chip comprises a switching device.

4. The semiconductor device of claim 1, wherein the second integrated circuit chip comprises a control device.

5. The semiconductor device of claim 1, wherein the conductive adhesive comprises solder.

6. The semiconductor device of claim 1, wherein the insulating adhesive tape has a single-layered structure comprising a polyimide base resin.

7. The semiconductor device of claim 6, wherein the polyimide base resin comprises thermosetting resin or thermoplastic resin.

8. The semiconductor device of claim 1, wherein the insulating adhesive tape has a multi-layered structure.

9. The semiconductor device of claim 8, wherein the multi-layered structure comprises a first adhesive layer, an insulating layer, and a second adhesive layer.

10. The semiconductor device of claim 9, wherein the first and second adhesive layers comprise a polyimide base resin.

11. The semiconductor device of claim 10, wherein the polyimide base resin comprises thermosetting resin or thermoplastic resin.

12. A power semiconductor device having a multi-chip package structure, the power semiconductor device comprising:
a lead frame;
a switching device attached to a top surface of the lead frame by a conductive adhesive, wherein the switching device does not have a passivation layer on a top surface of the switching device; and
a driving device attached to the top surface of the switching device by an insulating adhesive tape.

13. The power semiconductor device of claim 12, wherein the driving device is directly attached to a top surface of the switching device by an insulating adhesive tape.

14. The power semiconductor device of claim 12, wherein the switching device comprises a transistor chip.

15. The power semiconductor device of claim 12, wherein the driving device comprises a control integrated circuit chip.

16. The power semiconductor device of claim 12, wherein the conductive adhesive comprises solder.

17. The power semiconductor device of claim 12, wherein the insulating adhesive tape has a single-layered structure comprising a polyimide base resin.

18. The power semiconductor device of claim 17, wherein the polyimide base resin comprises thermosetting resin or thermoplastic resin.

19. The power semiconductor device of claim 12, wherein the insulating adhesive tape has a multi-layered structure.

20. The power semiconductor device of claim 19, wherein the multi-layered structure comprises a first adhesive layer, an insulating layer, and a second adhesive layer.

21. The power semiconductor device of claim 20, wherein the first and second adhesive layers comprise a polyimide base resin.

22. The power semiconductor device of claim 21, wherein the polyimide base resin comprises thermosetting resin or thermoplastic resin.

23. A semiconductor device having a multi-chip package structure, the semiconductor device comprising:
a lead frame;
a first integrated circuit chip attached to a top surface of the lead frame by a conductive adhesive, wherein the first integrated circuit chip does not have a passivation layer on a top surface of the first integrated circuit chip; and
a second integrated circuit chip directly attached to the top surface of the first integrated circuit chip by an insulation epoxy adhesive.

24. The semiconductor device of claim 23, wherein the first integrated circuit chip comprises a switching device.

25. The semiconductor device of claim 23, wherein the second integrated circuit chip comprises a control device.

26. The semiconductor device of claim 23, wherein the conductive adhesive comprises solder.

27. The semiconductor device of claim 23, wherein the insulation epoxy adhesive comprises a thermosetting liquid epoxy, and wherein a plurality of beads are included with the insulation epoxy adhesive.

28. The semiconductor device of claim 27, wherein the beads comprise silica.

29. The semiconductor device of claim 27, wherein the beads have a diameter of about 25 μm to about 100 μm.

30. A power semiconductor device having a multi-chip package structure, the power semiconductor device comprising:
a lead frame;
a switching device attached to a top surface of the lead frame by a conductive adhesive, wherein the switching device does not have a passivation layer on a top surface of the switching device; and
a driving device directly attached to the top surface of the switching device by an insulation epoxy adhesive.

31. The power semiconductor device of claim 30, wherein the switching device comprises a transistor chip.

32. The power semiconductor device of claim 30, wherein the driving device comprises a control integrated circuit chip.

33. The power semiconductor device of claim 30, wherein the conductive adhesive comprises solder.

34. The power semiconductor device of claim 30, wherein the insulation epoxy adhesive comprises a thermosetting liquid epoxy, and wherein a plurality of beads are included with the insulation epoxy adhesive.

35. The power semiconductor device of claim 34, wherein the beads comprise silica.

36. The power semiconductor device of claim 34, wherein the beads have a diameter of about 25 μm to about 100 μm.

37. A method of manufacturing a semiconductor device having a multi-chip package, the method comprising:
attaching a first integrated circuit chip to a top surface of a lead frame with a conductive adhesive, wherein the first integrated circuit chip does not have a passivation layer on a top surface of the first integrated circuit chip; and
attaching a second integrated circuit chip to the top surface of the first integrated circuit chip with an insulating adhesive tape.

38. The method of claim 37, wherein attaching a second integrated circuit chip comprises directly attaching a second integrated circuit chip to a top surface of the first integrated circuit chip with an insulating adhesive tape.

39. The method of claim 37, wherein the first integrated circuit chip comprises a switching device.

40. The method of claim 37, wherein the second integrated circuit chip comprises a control device.

41. The method of claim 37, wherein the insulating adhesive tape comprises a polyimide base resin.

42. The method of claim 41, wherein the polyimide base resin comprises thermosetting resin or thermoplastic resin.

43. A method of manufacturing a power semiconductor device having a multi-chip package, the method comprising:
attaching a switching device to a top surface of a lead frame with a conductive adhesive, wherein the switching device does not have a passivation layer on a top surface of the switching device; and
attaching a driving device to the top surface of the switching device with an insulating adhesive tape.

44. The method of claim 43, wherein attaching a driving device comprises directly attaching a driving device to a top surface of the switching device with an insulating adhesive tape.

45. The method of claim 43, wherein the switching device comprises a transistor chip.

46. The method of claim 43, wherein the driving device comprises a control integrated circuit chip.

47. The method of claim 43, wherein the insulating adhesive tape comprises a polyimide base resin.

48. The method of claim 47, wherein the polyimide base resin comprises thermosetting resin or thermoplastic resin.

49. A method of manufacturing a semiconductor device having a multi-chip package, the method comprising:
attaching a first integrated circuit chip to a top surface of a lead frame with a conductive adhesive, wherein the first integrated circuit chip does not have a passivation layer on a top surface of the first integrated circuit chip; and
directly attaching a second integrated circuit chip to the top surface of the first integrated circuit chip with an insulation epoxy adhesive.

50. The method of claim 49, wherein the first integrated circuit chip comprises a switching device.

51. The method of claim 49, wherein the second integrated circuit chip comprises a control device.

52. The method of claim 49, wherein the insulation epoxy adhesive comprises a thermosetting liquid epoxy, and wherein a plurality of beads are included with the insulation epoxy adhesive.

53. The method of claim 52, wherein the beads comprise silica.

54. The method of claim 52, wherein the beads have a diameter of about 25 μm to about 100 μm.

55. A method of manufacturing a power semiconductor device having a multi-chip package, the method comprising:
attaching a switching device to a top surface of a lead frame with a conductive adhesive, wherein the switching device does not have a passivation layer on a top surface of the switching device; and
directly attaching a driving device to the top surface of the switching device with an insulation epoxy adhesive.

56. The method of claim 55, wherein the first integrated circuit chip comprises a switching device.

57. The method of claim 55, wherein the second integrated circuit chip comprises a control device.

58. The method of claim 55, wherein the insulation epoxy adhesive comprises a thermosetting liquid epoxy, and wherein a plurality of beads are included with the insulation epoxy adhesive.

59. The method of claim 58, wherein the beads comprise silica.

60. The method of claim 58, wherein the beads have a diameter of about 25 μm to about 100 μm.
